(19) United States
(12) Patent Application Publication
(10) Pub. No.: US 2026/0271660 A1
(43) Pub. Date: Sep. 10, 2026

(54) WAFER BOAT HANDLING SYSTEM AND OPERATION METHOD THEREOF

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Xiao JIN, Shanghai City (CN); Lan ZHANG, Shanghai City (CN); Chunjie GAO, Shanghai City (CN); Pianpian ZHOU, Shanghai City (TW); Xin ZHAO, Shanghai City (TW)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/081,927

(22) Filed: Mar. 17, 2025

(30) Foreign Application Priority Data
Mar. 5, 2025 (CN) 202520381615.7

(51) Int. Cl. H01L 21/67; B65G 47/90; H01L 21/306; H01L 21/677

(52) U.S. Cl. CPC H10P 72/0606; B65G 47/90; H10P 50/642; H10P 72/3404

(57) ABSTRACT

A method includes placing a wafer boat including one or more semiconductor wafers onto an automated mechanism platform apparatus mounted on a shelf of a first rack, wherein the automated mechanism platform apparatus includes a rotor and a turntable over the rotor; utilizing a position detection system to verify a placement of the wafer boat on the turntable; rotating the wafer boat on the turntable to adjust an orientation of the wafer boat.

### PRIORITY CLAIM AND CROSS-REFERENCE

This application claims priority to CN Application Serial Number 202520381615.7, filed Mar. 5, 2025, which is herein incorporated by reference.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a fabrication facility in accordance with some embodiments of the present disclosure.

FIG. 2 illustrates a semiconductor fabrication plant including trolleys, production tools, stockers, and a wafer transport channel in accordance with some embodiments of the present disclosure.

FIG. 3 is a flowchart illustrating a method for semiconductor manufacturing in accordance with some embodiments of the present disclosure.

FIGS. 4A to 4C illustrate the cross-sectional views of intermediate stages in the formation of a semiconductor structure over a substrate in accordance with some embodiments.

FIGS. 5A and 5B illustrate schematic views of a wafer boat and a wafer carrier in accordance with some embodiments of the present disclosure.

FIGS. 6A to 8B illustrate schematic views of various stages of a method for automatically moving (e.g., rotating) wafers by an automation mechanism platform apparatus in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

This disclosure provides a method to solve an issue of manually grabbing a semiconductor boat from an unsafe position after it is placed on a storage shelf by a transfer module. In some embodiments, grabbing the semiconductor boat from positions other than its handle may pose a risk of dropping it, which can be hazardous. Moreover, the semiconductor boat might have been exposed to strong acids in earlier processes, making any area other than the handle unsafe for handling. Therefore, the present disclosure in various embodiments provides an automatic turntable that can allow for a semiconductor boat to be rotated such that its handle is positioned for a human operator. The process can be automated to ensure that the handle of the semiconductor boat can ends up on the accessible side for personnel, thereby eliminating unsafe manual operations and promoting automation.

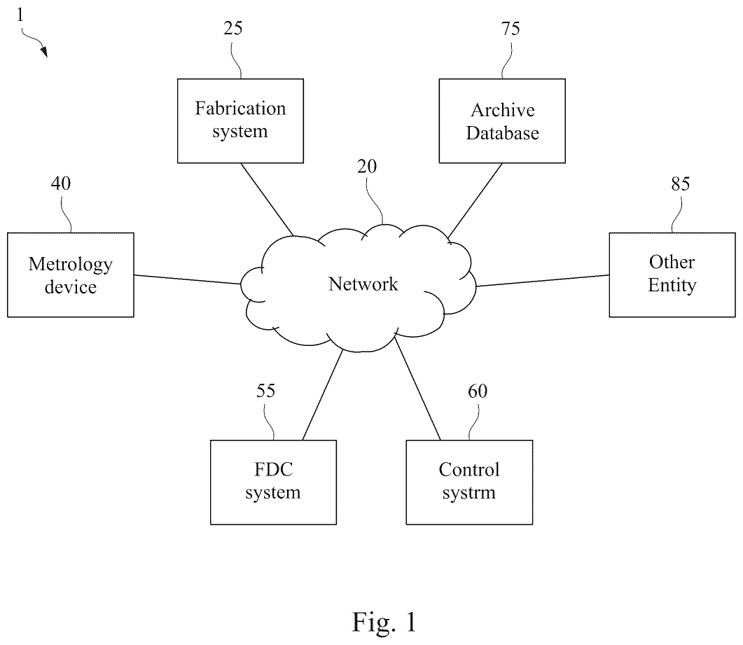

Reference is made to FIG. 1. FIG. 1 is a block diagram of a fabrication facility in accordance with some embodiments of the present disclosure. The fabrication facility 1 implements integrated circuit manufacturing processes to fabricate integrated circuit devices. For example, the fabrication facility 1 may implement semiconductor manufacturing processes that fabricate semiconductor wafers. It should be noted that, in FIG. 1, the fabrication facility 1 has been simplified for the sake of clarity to better understand the concepts of the present disclosure. Additional features can be added in the fabrication facility 1, and some of the features described below can be replaced or eliminated in other embodiments of the fabrication facility 1. The fabrication facility 1 may include more than one of each of the entities. In some embodiments, and may further include other entities not illustrated in the depicted embodiment. In some embodiments, the fabrication facility 1 can include a network 20 that enables various entities (a fabrication system 25, a metrology device 40, a fault detection and classification (FDC) system 55, a control system 60, an archive data base 70, and another entity 85) to communicate with one another. The network 20 may be a single network or a variety of different networks, such as an intranet, the Internet, another network, or a combination thereof. The network 20 may include wired communication channels, wireless communication channels, or a combination thereof.

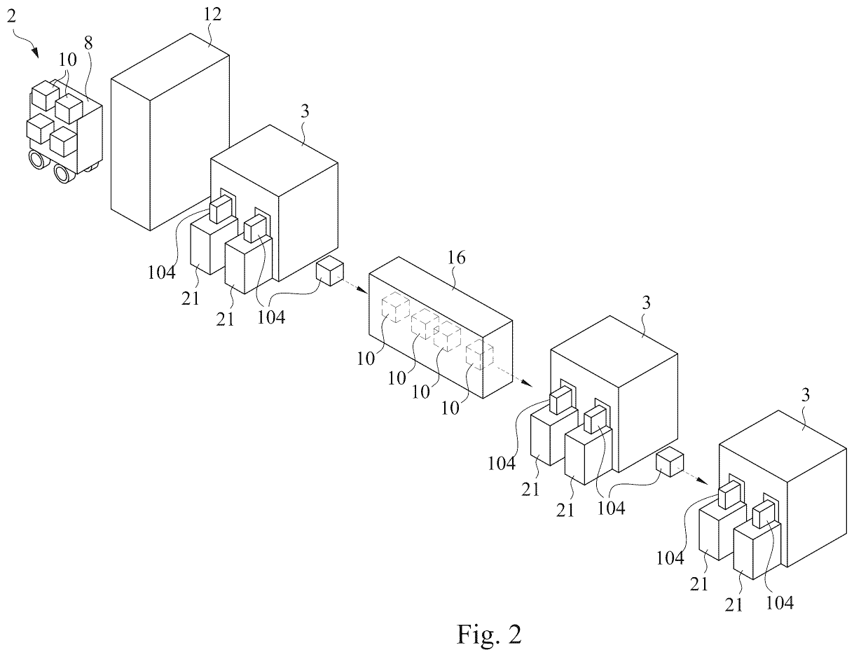

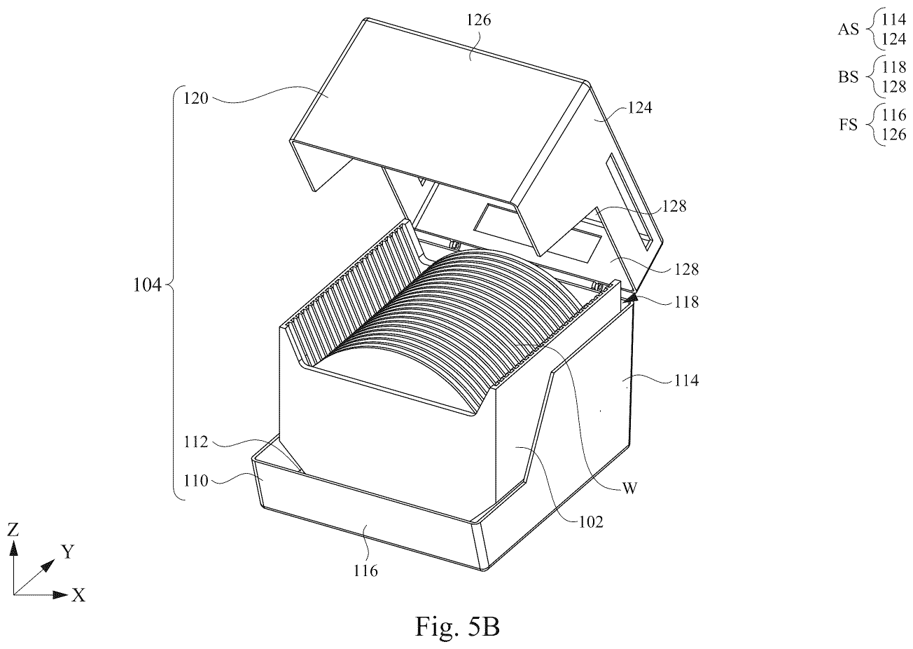

Reference is made to FIG. 2. FIG. 2 illustrates an exemplary manufacturing line 2 implementing integrated circuit manufacturing processes to fabricate integrated circuit devices. For example, the manufacturing line 2 may implement semiconductor manufacturing processes that fabricate semiconductor wafers. It should be noted that, in FIG. 2, the manufacturing line 2 has been simplified for the sake of clarity to better understand the concepts of the present disclosure. As shown in FIG. 2, the manufacturing line 2 may include production tools 3. The manufacturing line may further include a trolley 8, a stocker 12, and a wafer transport channel 16. The trolley 8 and wafer transport channel 16 can be used to transport wafer boats 102 (see FIGS. 5A and 5B)/wafer carriers 104. In some embodiments, the wafer boats 102/wafer carriers 104 can be made of quartz and/or polypropylene (PP). In some embodiments, wafer boat 102/the wafer carrier 104 can be interchangeably referred to as wafer holders, cassettes, or front opening unified pods (FOUPs). In some manufacturing processes, wafers need to go through one or more of the above-discussed tools. For example, the wafer carriers 104 may be transported by the trolley 8 into the stocker 12, which has a wafer storage for storing wafers. The wafer boats 102/wafer carriers 104 may also be transported to the load ports 21, which load wafers into and take wafers out of the production tools 3. The production tools 3 can perform manufacturing steps to the wafers. The transportation between the production tools 3 may be performed using the trolleys 8 or the automatic wafer transport channel 16. In some embodiments, the tool can be interchangeably referred to as an apparatus.

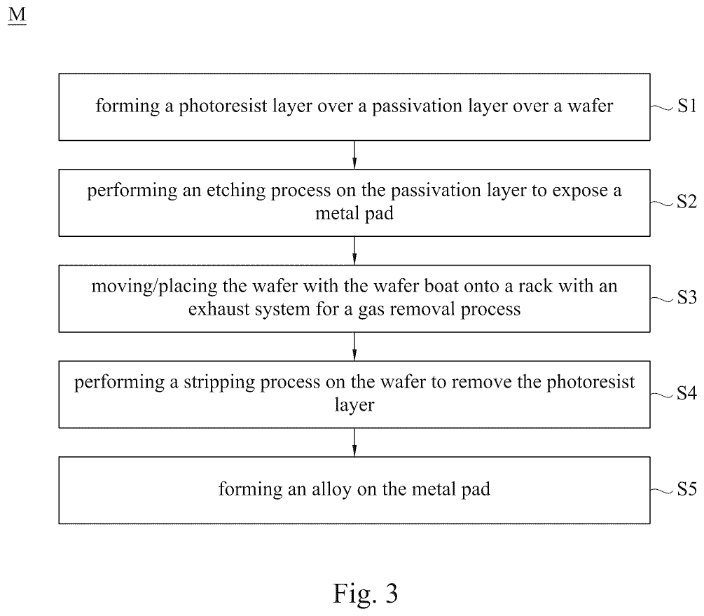

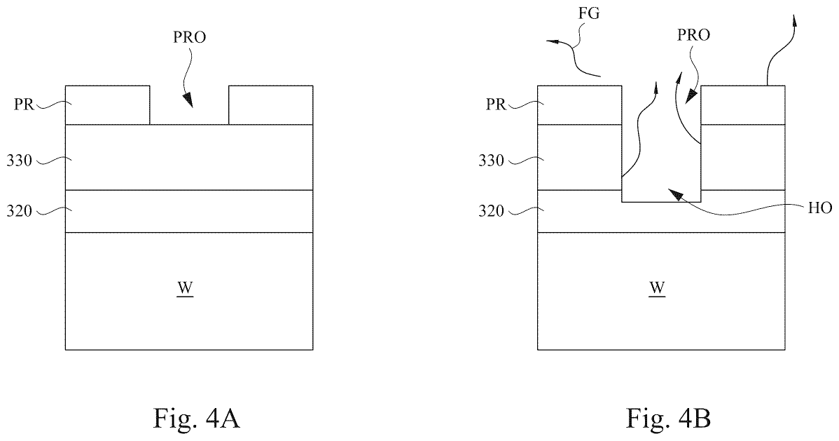

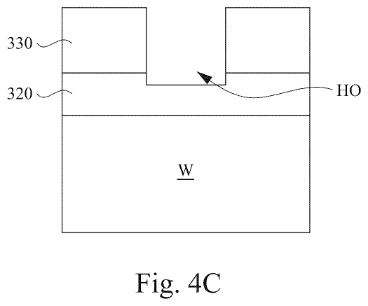

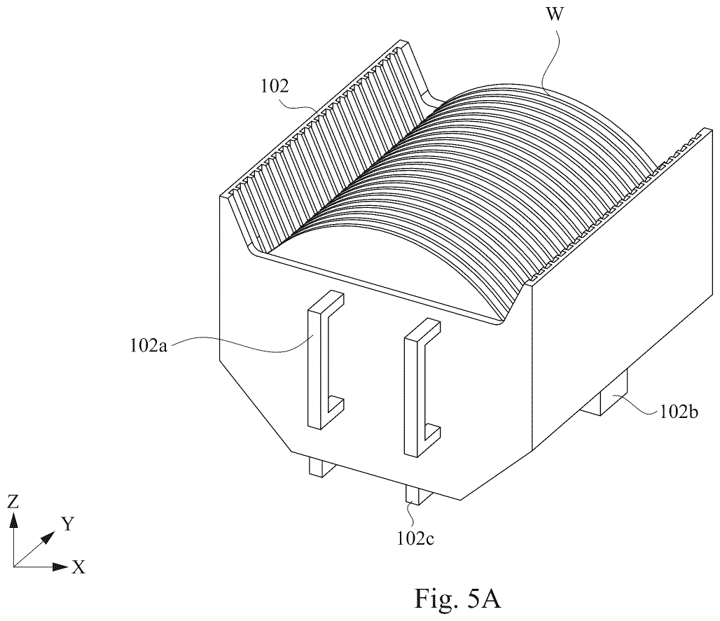

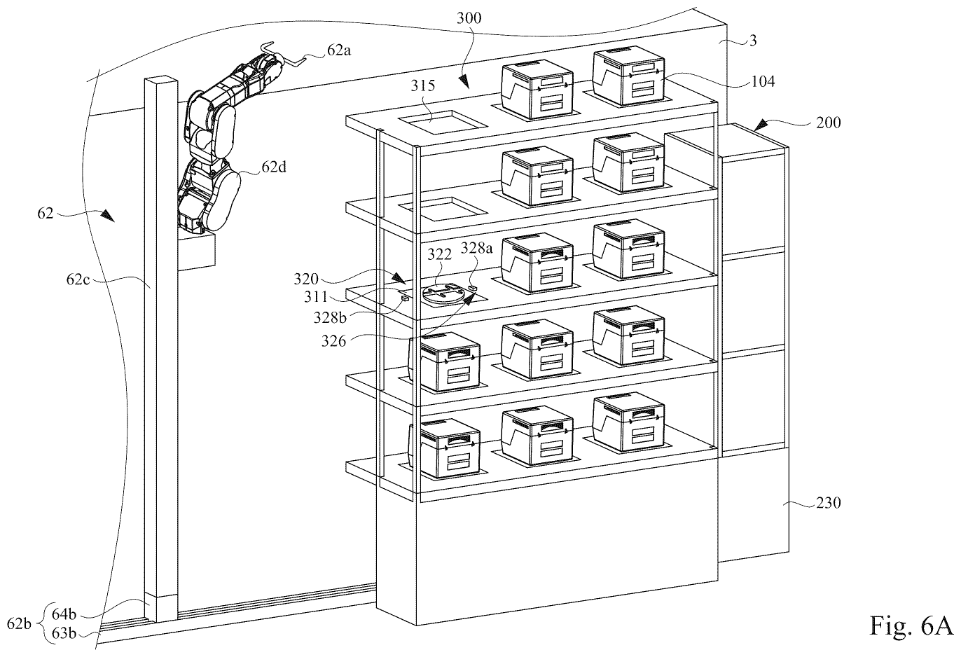

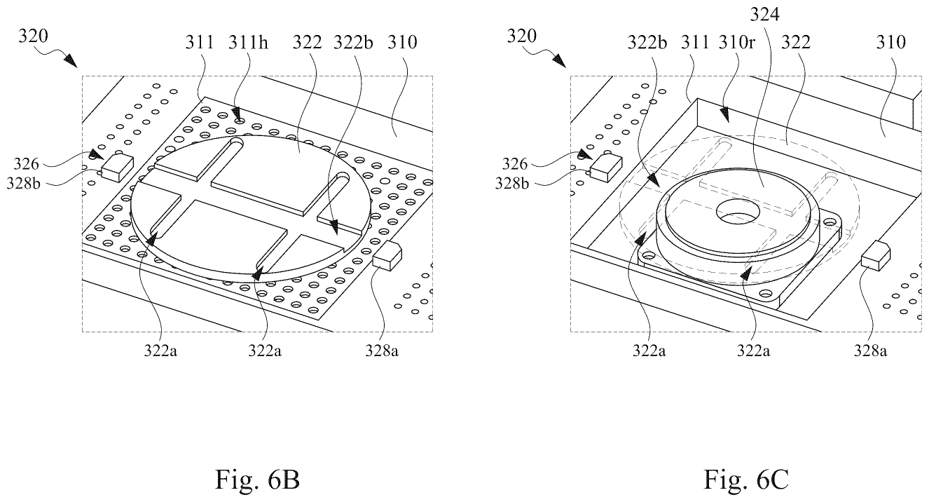

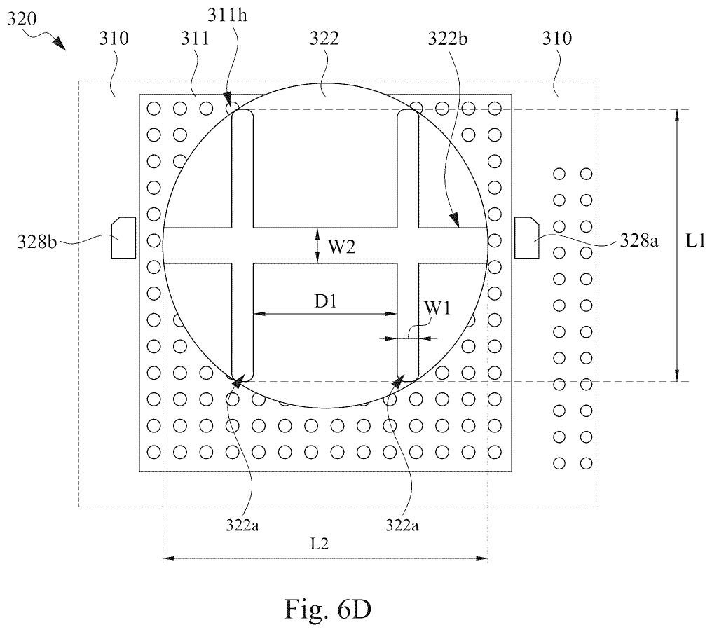

Reference is made to FIGS. 3 to 5B. FIG. 3 is a flow chart of a method M for processing a wafer according to some embodiments of the present disclosure. FIGS. 4A to 4C illustrate various stages of the method M in accordance with some embodiments of the present disclosure. FIGS. 5A and 5B illustrate schematic views of a wafer boat 102 and a wafer carrier 104 in accordance with some embodiments of the present disclosure. The method M may include steps S1-S6. At step S1, forming a photoresist layer PR over a passivation layer 330 over a wafer W. At step S2, performing an etching process on the passivation layer 330 to expose a metal pad 325. At step S3, placing the wafer W onto a wafer boat 102, and then moving the wafer boat onto a rack 200 (see FIG. 6A) with an exhaust system for a gas removal process. At step S4, performing a stripping process on the wafer W to remove the photoresist layer PR. At step S5, forming an alloy on the metal pad 325. It is understood that additional steps may be provided before, during, and after the steps S1-S5 shown in FIG. 3, and some of the steps described below can be replaced or eliminated for additional embodiments of the method. The order of the operations/processes may be interchangeable.

Reference is made to FIG. 3 and FIG. 4A. The method M begins at step S1, where the photoresist layer PR can be formed over the passivation layer 330 over the wafer W. The wafer W may be referred to as a semiconductor substrate. The wafer W may be made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide (GaAs), indium gallium arsenide (InGaAs), indium arsenide (InAs), indium phosphide (InP), indium antimonide (InSb), gallium arsenic phosphide (GaAsP), or gallium indium phosphide (GaInP)), or the like. Further, the wafer W may include an epitaxial layer (epi-layer), which may be strained for performance enhancement, and/or may include a silicon-on-insulator (SOI) structure.

In some embodiments, one or more active and/or passive devices can be formed on the wafer W. An interconnect structure may be formed over the active and/or passive devices. The interconnect structure may include a metallization pattern comprising metal lines extending horizontally and metal vias extending vertically in dielectric layers. Then, one or more metal pads 325 (also referred to as a top metal layer) can be then formed over the interconnect structure to be in direct contact with the underlying metallization pattern in the interconnect structure. Thus, the metal pads 325 can be electrically connected the underlying metallization pattern in the interconnect structure. The metal pads 325 may be formed of aluminum, aluminum copper, aluminum alloys, copper, copper alloys, or the like. For example, the metal pad 325 includes AlCu pad. The metal pads 325 may also be referred to as bond pads. The passivation layer 330 is formed to cover the metal pads 325. The passivation layer 330 may be formed of a dielectric material, such as undoped silicate glass (USG), silicon nitride, silicon oxide, silicon oxynitride or a non-porous material by any suitable method, such as CVD, PVD, or the like. The passivation layer 330 may be a single layer or a laminated layer. It is noted that a single layer of metal pads 325 and a passivation layer 330 are shown for illustrative purposes only. As such, other embodiments may include any number of metal pads and/or passivation layers.

The photoresist layer PR can be formed over the passivation layer 330 by a photolithography process, for example. The photolithography processes may include photoresist coating (e.g., spin-on coating), soft baking, mask aligning, exposure, post-exposure baking, developing the photoresist, rinsing, drying (e.g., hard baking), and/or other applicable processes. The photoresist layer PR has an opening PRO exposing the underlying passivation layer 330.

Reference is made to FIGS. 3 and 4B. The method M proceeds to step S2, where the passivation layer 330 can be etched to expose a metal pad 325 by the production tool 3 (see FIG. 2). In some embodiments, an etching process, such as a wet etch process can be performed by soaking the wafer W in the process chamber (e.g., acid tank with acid precursor) containing a liquid (e.g., the etching solution) in the production tool 3, and the wafer boat 102 (see FIGS. 5A and 5B) can be simultaneously soaked in the process chamber. In some embodiments, the etching solution may be HF and buffered oxide etchant (BOE). In some alternative embodiments, the etching solution may be ammonia-peroxide mixture (APM) (e.g., a mixture of NH₄OH, H₂O₂, and water), H₃PO₄, the like, or the combination thereof. In some embodiments, the acid tank can be adapted to perform processes such as cleaning, etching, or surface preparation of the wafers W to ensure proper removal of contaminants or to modify the surface characteristics of the wafers for subsequent manufacturing stages.

In some embodiments, an etching process, such as a dry etch process (e.g., using an acid precursor, such as a fluorine-containing gas) can be performed using the photoresist layer PR as an etch mask, such that a first portion of the passivation layer 330 exposed by the opening PRO of the photoresist layer PR can be removed by being etched, and a second portion of the passivation layer 330 covered by the photoresist layer PR can be protected from being etched. As a result, an opening HO can be etched in the passivation layer 330 according to the profile and location of the opening PRO of the photoresist layer PR. In some embodiments, the metal pad 325 can be slightly consumed by the dry etch process, such that a top surface of a first portion of the metal pad 325 exposed by the opening HO can be lower than a top surface of a second portion of the metal pad 325 covered by the passivation layer 330.

In some embodiments, the dry etch process for etching the passivation layer 330 can use a fluorine-containing gas, such as SF₆, CF₄, CHF₃, the like, or the combination thereof. After the dry etch process is completed, fluoride will remain on sidewalls of the photoresist layer PR and the metal pad 325, and the fluorine-containing gas FG may outgas from the wafer W. For example, the fluorine-containing gas FG with fluorine particles can be released from the wafer W. In absence of effectively removing the fluorine-containing gas FG outgassing from the wafer W, a reaction between the fluorine-containing gas FG and exposed metal pad 325 (e.g., AlCu metal pad) after the passivation etching process can occur. Crystals may grow on passivation window, thereby forming the pad defects before the packaging. The pad defects may cause bonding failure and reduce the wafer reliability. Sometimes, the pad defects may cause wafer scrapping and reduce manufacture yield rate.

Reference is made to FIGS. 3 and 4B. The method M proceeds to step S3, where the wafer W with the wafer boat 102 (see FIG. 5A) can be moved/placed onto the rack 200 (see FIG. 6A) for a gas removal process. The wafer boat 102 may include plural slots/fixtures for holding plural wafers W and spacing the wafers W from each other. In some embodiments, the wafer boat 102 assumes an angle with respect to the horizontal so that wafers W can be induced to rest on their respective rear surfaces and the front or upper surfaces of the wafers W are not in contact with anything. In some embodiments, the wafer boat 102 does not substantially enclose the wafers W. As a result, when the wafer boat 102 is moved/placed onto the rack 200, the wafers W can be exposed to the space in the rack 200 which can be fluid communicated with the environment and an exhaustion system 230 (see FIG. 6A). In some embodiments, the wafer boat 102 may include tags revealing identities of the wafers W, and can be used at various stages of the process.

In some embodiments of the present disclosure, by moving/placing the wafer boat 102 (see FIG. 5A) onto the rack 200 (see FIG. 6A) with the exhaustion system 230, the gas removal process is performed, in which the exhaustion system 230 can effectively remove the fluorine-containing gas FG with fluorine particles that can be released from the wafer W. Thus, the generation of crystals on the passivation window can be inhibited. As a result, the pad defects can be reduced. In some embodiments, the wafers W can stand substantially along the direction Z on the wafer boat 102, and the gas flow GF generated by the exhaustion system 230 flows substantially along the direction Z. With this configuration, the gas flow GF can flow across the plural wafers W in a more uniform manner. In some embodiments, wafer boat 102 may further be placed in the wafer carrier 104.

As shown in FIG. 5B, the wafer boat 102 can be disposed in the wafer carrier 104. The wafer carrier 104 can be a box structure, and illustratively, the wafer carrier 104 can include a lower box 110 and an upper cover 120, and a space for accommodating a wafer boat 102 can be disposed between the lower box 110 and the upper cover 120. The lower box 110 and the upper cover 120 may be pivotally connected by a rotating shaft. Through the configuration, the wafer carrier 104 may be opened and closed by turning over the upper cover 120. For example, the upper cover 120 can be rotated with respect to a direction X for opening or closing the wafer carrier 104. In some embodiments of the present disclosure, the lower box 110 and the upper cover 120 of the wafer carrier 104 may have one or more openings. Through the configuration, a space in the wafer carrier 104 is fluidly communicated with the environment.

The lower box 110 has a bottom box plate 112, two side box plates 114, a front box plate 116, and a back box plate 118. The upper cover 120 has a top cover plate 122, two side cover plates 124, a front cover plate 126, and a back cover plate 128. The front box plate 116 of the lower box 110 and the front cover plate 126 of the upper cover 120 can meet each other and form the front side FS of the wafer carrier 104. The back box plate 118 of the lower box 110 and the back cover plate 128 of the upper cover 120 can meet each other and form a back side BS of the wafer carrier 104. One of the side box plates 114 of the lower box 110 and one of the side cover plates 124 of the upper cover 120 can meet each other and form a lateral side AS of the wafer carrier 104, and the other one of the side box plates 114 of the lower box 110 and the other one of the side cover plates 124 of the upper cover 120 can meet each other and form another lateral side AS of the wafer carrier 104. In some embodiments of the present disclosure, the upper cover 120 and the lower box 110 may have plural openings allowing the gas outgassing from a wafer to leave the wafer carrier 104. As shown in FIGS. 5A and 5B, the wafer W can be moved/placed onto the wafer boat 102.

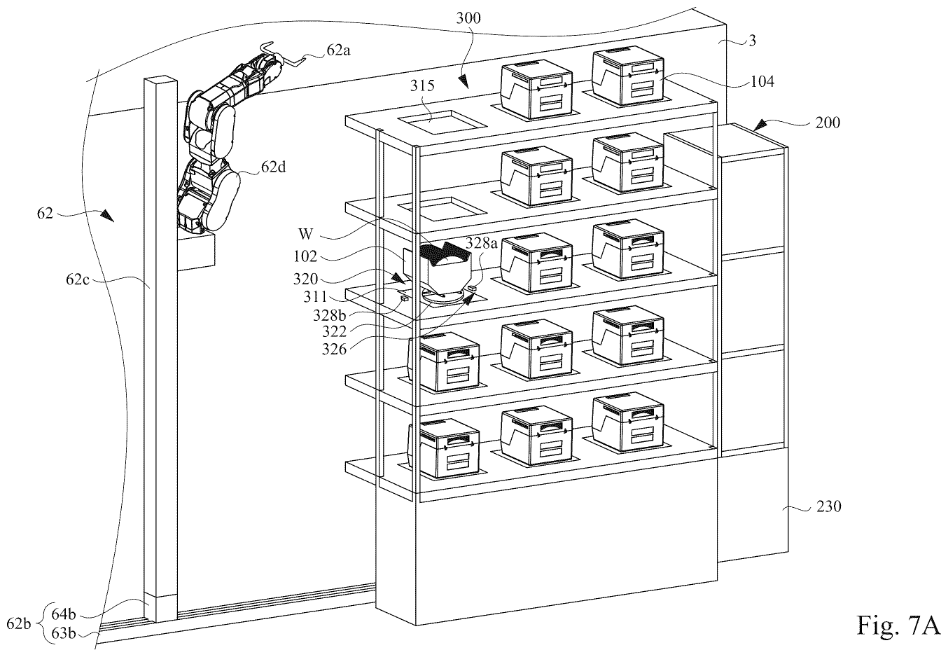

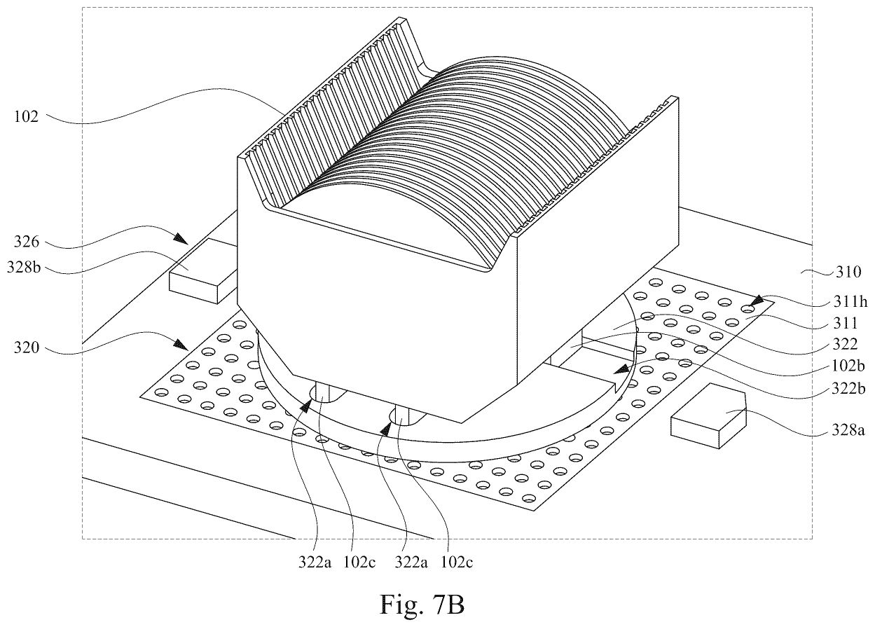

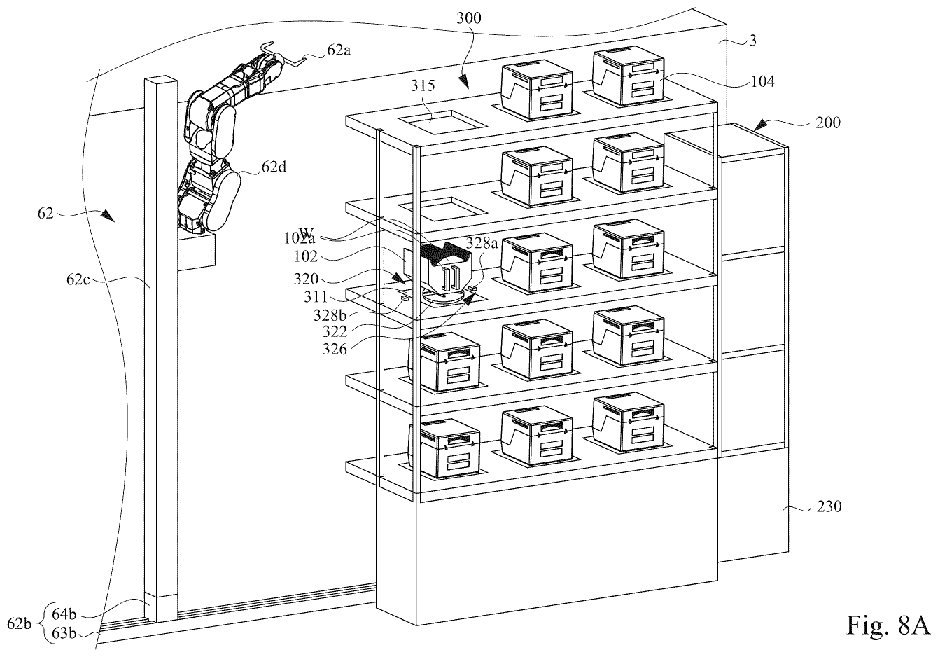

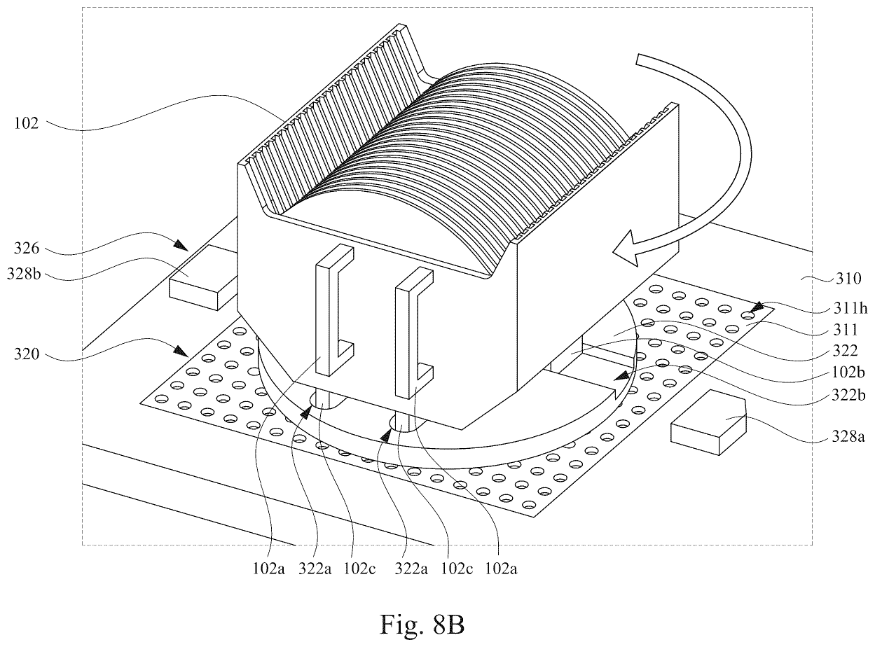

Reference is made to FIGS. 6A-8B. After completing the gas removal process in rack 200, the wafers W can be moved to rack 300 using the wafer boat 102 (see FIGS. 7A and 7B). Subsequently, the wafer boat 102 carrying wafers W (see FIGS. 8A and 8B) can be rotated in position by the automated mechanism platform apparatus 320 located on rack 300 to facilitate the next stage of processing. For instance, the wafer boat 102 can be rotated by 180 degrees using the automated mechanism platform apparatus 320 on the rack 300, positioning the handle 102a of wafer boat 102 (see FIGS. 8A and 8B) to face away from the side of rack 300 that is adjacent to the production tool 3. This configuration can allow the movement apparatus in the manufacturing line 2 to use the handle 102a of wafer boat 102 to transport it. In some embodiments, manual handling by personnel can be used instead of the automated movement apparatus. In other embodiments, rotating the wafer boat 102 using the automated mechanism platform apparatus 320 on rack 300 can change the orientation of wafers W so the wafers W can be positioned differently for the next process stage. By employing the automated mechanism platform apparatus 320 for rotating wafer boat 102, vertical movements are avoided during the horizontal rotation process. This approach can reduce the chance of vertical vibrations, which minimizes the risk of damage and contamination to the wafers W.

Reference is made to FIGS. 6A to 6D. As shown in FIG. 6A, the rack 300 can be positioned on one side of the production tool 3, while the rack 200 can be placed on another side of the production tool 3. Between the racks 300 and 200 and the production tool 3, a transfer module 62 may be installed to facilitate the movement of wafer boats 102 (see FIGS. 5A and 5B) or wafer carriers 104. The transfer module 62 can allow the wafer boats 102 or wafer carriers 104 to be transported smoothly along a path between racks 300 and 200 and the production tool 3, ensuring efficient and precise handling during the semiconductor manufacturing process.

Specifically, the transfer module 62, integrated within the racks 200 and 300 can include components that coordinate to manipulate and transport wafer boats 102/wafer carriers 104 with high precision across various dimensions and orientations. In some embodiments, the transfer module 62 can include a wafer container gripper 62a for securely holding the wafer boat 102/wafer carrier 104 during transit. The gripper can be in various shapes and sizes to accommodate different container specifications, ensuring a firm and safe grip without damaging the contents. In some embodiments, the transfer module 62 can further include a linear actuator 62b including a horizontal slide rail 63b and a movable carrier 64b, the linear actuator can facilitate smooth horizontal movements along the rail, and the actuator can power these movements, allowing for precise positioning along the X-axis within the facility. In some embodiments, the transfer module 62 can further include a lifter 62c equipped with a vertical slide rail and a movable carrier operated by an actuator, the lifter 62c can enable vertical movement, allowing the transfer module 62 to adjust the elevation of wafer boats 102/wafer carriers 104, accommodating different tiers within the rack 300/200 or aligning with equipment at various heights. In some embodiments, the transfer module 62 can further include a rotor 62d to control the rotational movements of the transfer module 62, enhancing the ability of the wafer container gripper 62a to adjust orientations.

Therefore, the wafer container gripper 62a can move seamlessly in three directions (e.g., horizontally along the X and Y axes and vertically along the Z axis). This multidirectional capability can be used for navigating the layout of semiconductor manufacturing facilities. On the other hand, the transfer module 62 can be capable of omnidirectional movement, achieving a high degree of freedom in operating the wafer boats 102/wafer carriers 104. In some embodiments, each component, such as the linear actuator 62b, the lifter 62c, and the rotor 62d in the transfer module 62 can be independently controlled and finely tuned to accelerate or decelerate smoothly. This precise control can help prevent any positional shifts of the wafer containers during rapid movements or transitions, safeguarding the integrity of the wafers. In some embodiments, the transfer module 62 can include a robot.

Specifically, the rack 300 can be equipped with multiple shelves 310 at different heights. Each shelf 310 can accommodate at least one wafer boat 102 or at least one wafer carrier 104, allowing the wafers W in the wafer boats 102 and/or the wafer carriers 104 to be properly staged for the next processing step. On each shelf 310, there is an automated mechanism platform apparatus 320 and a carrier support base 315. The wafer boats 102 can be positioned on the automated mechanism platform apparatus 320, while the wafer carriers 104 are placed on the carrier support base 315. This setup can ensure that both wafer boats and carriers are securely positioned, ready for subsequent automated handling or processing stages. The length direction of shelf 310 in the rack 300 can extends along the horizontal slide rail 63b, creating a spatial relationship that can align with the movement path of wafer boats 102 and the wafer carriers 104, ensuring efficient transportation and positioning of wafer boats 102 and the wafer carriers 104 for various stages of semiconductor processing.

The automated mechanism platform apparatus 320 and the carrier support base 315 can be arranged on the rack 300 in a matrix configuration. Specifically, multiple instances of automated mechanism platform apparatus 320 and carrier support base 315 can be distributed across different positions on each shelf 310, allowing for versatile placement options and facilitates efficient use of the rack's capacity. By way of example and not limitation, along the length direction of the horizontal slide rail 63b, up to three automated mechanism platform apparatuses 320 and/or carrier support bases 315 can be installed side-by-side. Along the direction perpendicular to the horizontal slide rail 63b, there may be four automated mechanism platform apparatuses 320 and/or carrier support bases 315 arranged. This matrix arrangement enables each shelf 310 to accommodate up to twelve units, optimizing both space utilization and accessibility for automated wafer handling.

In some embodiments, the wafer carrier 104 placed on the carrier support base 315 may remain stationary, while the wafer boats 102 placed on the automated mechanism platform apparatus 320 may be rotated horizontally, allowing for selective rotation of the wafer boats 102 to properly orient the wafers W for subsequent processing stages. In some embodiments, on the same shelf 310, the carrier support base 315 can be positioned next to the automated mechanism platform apparatus 320 without an additional automated mechanism platform apparatus being installed. This arrangement can optimize the use of space, ensuring that both stationary and rotating components can be accommodated efficiently. In some embodiments, multiple automated mechanism platform apparatuses 320 can be installed adjacently on the same shelf 310. This arrangement can allow for the handling of multiple wafer boats simultaneously, improving throughput and efficiency. Additionally, in some configurations, within the rack 300, the automated mechanism platform apparatus 320 and the carrier support base 315 may be aligned in the same column but positioned on different shelves 310. This vertical arrangement can help in organizing the workflow, ensuring that both rotating wafer boats 102 and stationary wafer carriers 104 can be easily accessible while minimizing interference between them.

As shown in FIGS. 6B to 6D, the automated mechanism platform apparatus 320 can include a turntable 322, a rotor 324 (see FIG. 6C), and a position detection system 326. The rotor 324 can rotate the turntable 322 to adjust the orientation of the wafer boat 102 and the wafers W (see FIGS. 7A-8B) in relation to the rack 300, allowing for optimized positioning during processing. In some embodiments, the height of the horizontal slide rail 63b is positioned below the height of the rotor 324 and the turntable 322, such that the wafer boats 102 can be easily lifted from the horizontal slide rail 63b to the turntable 322 for subsequent processing, allowing for efficient integration of the transportation system and the automated mechanism platform apparatus 320. In some embodiments, the rotor 324 may be a rotating micro motor that can provide precise rotational control. In some embodiments, the shelf 310 can be designed with a recess 310r (see FIG. 6C), which can be covered by a protective plate 311 (see FIGS. 6A, 6B, and 6D). The protective plate 311 can be mounted on the shelf 310 and include multiple periodically arranged holes 311h (see FIGS. 6B and 6D) to facilitate ventilation. The rotor 324 as shown in FIG. 6C can be located within the recess 310r of the shelf 310 and extend through the protective plate 311, with the turntable 322 connected to the upper end of the rotor and positioned outside of the recess 310r.

In some embodiments, as shown in the top view of FIG. 6D, the holes 311h of the protective plate 311 can be arranged around the turntable 322. The holes 311h can facilitate the movement of air around the wafer boat 102 (see FIGS. 7B and 8B), providing consistent airflow across the entire area where the wafers W are located, which in turn helps in removing any stagnant air pockets, reducing the buildup of heat, and maintaining uniform environmental conditions around the wafers. Additionally, during the wafer handling process, various components such as the rotor 324 (see FIG. 6C) may generate heat. The holes 311h can allow heat to dissipate effectively by promoting natural or forced air circulation around the turntable and wafer boat, which in turn helps maintain the temperature within a safe range, thereby protecting the wafers from thermal damage that could affect their quality or lead to defects. Moreover, the holes 311h also can help in reducing the risk of contamination. By enabling proper ventilation, the holes 311h can facilitate the removal of particulate matter and gaseous by-products that might be present in the environment, which in turn prevents these contaminants from settling on the wafers W.

The turntable 322 can include trench 322a and trench 322b (see FIGS. 6B-6D). The trench 322a can be designed to receive the protruding strip feature 102c (see FIGS. 5A, 7B, and 8B) located on the bottom of wafer boat 102, ensuring that the wafer boat 102 can be securely positioned on the turntable 322. In some embodiments, the number of the multiple trenches 322a of the turntable 322 may corresponding to the number of the protruding strip features 102c on the bottom of wafer boat 102. In some embodiments, these trenches 322a can extend parallel to each other across the turntable 322. In some embodiments, the trenches 322a can be linear, while in others, the trenches 322a may be curved (rounding trenches). Moreover, different trenches 322a may have varying patterns. For example, one of the trenches 322a might be a linear trench, while another could be a rounding trench. In some embodiments, the ends of trench 322a can be located within the perimeter of turntable 322, whereas in other configurations, the ends of trench 322a might extend through the sidewalls of the turntable. This flexibility in design can allow the turntable 322 to accommodate different wafer boat structures and ensure stable positioning during rotational movement.

The trench 322b on the turntable 322 can work in conjunction with the position detection system 326 (e.g., a sensor) to determine whether the wafer boat 102 (see FIGS. 7A-8B) can be positioned in its designated location. Specifically, the position detection system 326 can be installed on the shelf 310 and monitor the alignment of the wafer boat 102. If the position detection system 326 detects any deviation from the expected position of the wafer boat 102, it can immediately send an abnormality alert to the fault detection and classification (FDC) system 55 (see FIG. 1). Upon receiving this alert, the operations related to the transfer module 62 can be promptly halted, enabling thorough inspection and maintenance of the internal components of the transfer module 62. This can ensure that any potential issues are addressed before they can lead to more problems, thereby maintaining operational safety and system reliability.

Specifically, the position detection system 326 can be capable of monitoring the light-blocking element 102b (see FIGS. 5A, 7B, and 8B) to detect any positional deviations of the wafer boat 102. When the protruding strip feature 102c of the wafer boat 102 is properly engaged with the trenches 322a on the turntable 322, the light-blocking element 102b can extend downwards into the trench 322b. This alignment can allow the position detection system to accurately verify that the wafer boat 102 is correctly seated in its designated location. If any misalignment occurs, the system can promptly detect it, thus ensuring proper positioning and stability, for subsequent automated handling and processing steps.

By way of example and not limitation, the position detection system 326 can include thrubeam sensors (or through-beams, or transmitted-beam sensors) and function through the arrangement of two separate components: a transmitter 328a mounted on the shelf 310 and at a first side of the trench 322b, and a receiver 328b mounted the shelf 310 and at a second side of the trench 322b opposite to the first side of the trench 322b. The transmitter 328a can emit optical beam, often infrared, which is aimed directly at the receiver 328b located on the opposite side. Detection is accomplished when a target (e.g., the light-blocking element 102b) intercepts the direct line of sight between the transmitter 328a and the receiver 328b. The interruption of the optical axis signals the presence of the light-blocking element 102b. The receiver 328b can be responsible for transducing the incoming optical signal into a corresponding electrical signal. This electrical signal is subsequently transmitted to the control system 60 (see FIG. 1), enabling it to ascertain the presence of the light-blocking element 102b.

As shown in FIG. 6D, the top view can illustrate that trenches 322a and trench 322b can form an H-shaped profile. In some embodiments, the trenches 322a and the trench 322b may form other profiles. In some configurations, the width W2 of the trench 322b can be greater than the width W1 of the trench 322a. However, in some embodiments, the width W2 of the trench 322b may be equal to or smaller than the width W1 of the trench 322a. Additionally, in some embodiments, the length L2 of the trench 322b can be greater than the length L1 of the trench 322a, although it is also possible for L2 to be equal to or less than L1 in different implementations. There may also be a spacing distance D1 between multiple trenches 322a. By way of example, but not limitation, the distance D1 can range between approximately 100 and 150 mm, such as about 100, 110, 120, 125, 130, 140, or 150 mm. These variations can allow for flexibility in adapting the trench dimensions to accommodate different wafer boat designs and provide secure positioning and handling during operations. By way of example, but not limitation, the width W1 of the trench 322a can be in a range from about 1 to 5 mm, such as 1, 2, 3, 4, or 5 mm. In some embodiments, the length L1 of the trench 322 can be in a range from about 100 to 300 mm, such as 100, 150, 190, 200, 250, or 300 mm. In some embodiments, the depth of the trench 322a can be in a range from about 1 to 10 mm, such as 1, 2, 3, 4, 5, 6, 7, 8, 9, or 10 mm.

Reference is made to FIGS. 7A and 7B. After the wafers W placed in wafer boat 102 complete the gas removal process in rack 200, the transfer module 62 can move wafer boat 102 to the rack 300. The wafer container gripper 62a of transfer module 62 can grab the wafer boat 102 from the rack 200. Subsequently, the linear actuator 62b can move the wafer boat 102 to the appropriate position while the lifter 62c assists in aligning wafer boat 102 with the corresponding automated mechanism platform apparatus 320 on the rack 300. Once aligned, the wafer container gripper 62a can place wafer boat 102 onto the designated automated mechanism platform apparatus 320. This sequence can ensure the precise handling and positioning of the wafer boat 102, facilitating the smooth transition of the wafers W between different stages of the semiconductor manufacturing process while minimizing the risk of misalignment or damage.

At this point, the transfer module 62 can notify the control system 60 (see FIG. 1) that the wafer boat 102 has been placed on the corresponding automated mechanism platform apparatus 320. Following this, the position detection system 326, located near the automated mechanism platform apparatus 320, can verify whether the wafer boat 102 has been accurately placed on the correct automated mechanism platform apparatus 320 and whether it is properly aligned, for ensuring that the wafer boat 102 is correctly positioned, which in turn helps maintain the integrity of subsequent automated processes. By confirming proper placement, the system can minimizes the risk of potential misalignment that could affect wafer processing and ensures that the production line operates efficiently and safely.

When the wafer boat 102 is in its default position, the light-blocking element 102b can be positioned within the trench 322b and aligned with the light signal's path, which is being transmitted and received by the sensor position detection system 326. The presence of the light-blocking element 102b in this path obstructs the light signal, preventing its receipt by the sensor's receiver 328b. Consequently, the receiver's output voltage, in this scenario, is high. The control system 60 can discern the position of the light-blocking element 102b. It can thus confirm that the wafer boat 102 is at the pre-determined position.

On the contrary, when the light-blocking element 102b is not in its default position, it is positioned externally to the trench 322b and does not impede the path of the light signal transmitted and received by the sensor position detection system 326. As such, the light-blocking element 102b doesn't interfere with the light signal, permitting its receipt by the receiver 328b. Consequently, the receiver's output voltage, in this scenario, is low. The control system 60 can discern that the light-blocking element 102b is not at the default position, by detecting the low voltage output. Therefore, this voltage differentiation can act as an effective monitoring and control mechanism for the system.

Reference is made to FIGS. 8A and 8B. In some embodiments, once the wafer boat 102 is positioned correctly on the turntable 322 of the automated mechanism platform apparatus 320, the wafer boat 102 can be rotated by the automated mechanism platform apparatus 320 to facilitate the next stage of wafer processing (see FIG. 8A). Specifically, the rotor 324 can rotate the turntable 322, causing the wafer boat 102, which is securely engaged with the turntable 322, to rotate accordingly. In some embodiments, the wafer boat 102 can be rotated such that the side with the handle 102a can be oriented toward the side of rack 300 facing away from the production tool 3. This orientation can allow the movement apparatus in manufacturing line 2 to use the handle 102a to move the wafer boat 102. In some embodiments, manual handling by personnel can replace the automated movement apparatus for transporting the wafer boat 102. Additionally, by using the automated mechanism platform apparatus 320 to rotate the wafer boat 102, vertical movement can be avoided during the horizontal rotation process, reducing the risk of vibration in the vertical direction. This precaution can help prevent potential damage to and contamination of the wafers W, thereby ensuring their integrity throughout the manufacturing process.

In some embodiments, after the wafer boat 102 is rotated on the turntable 322 by the automated mechanism platform apparatus 320, the wafers W inside the wafer boat 102 may be reoriented to prepare for the next stage of processing. The rotation can allow the wafers W to either continue into the same production tool 3 for additional processing steps or to move to different production tools 3 for subsequent operations. Therefore, the wafers W can be presented in specific orientations for optimal interaction with the equipment for different stages of wafer processing.

The rotation angle of the turntable 322 can range from 0 to 360 degrees. For example, the turntable 322 can rotate approximately 180 degrees. By way of example, but not limitation, the rotation angle of the turntable 322 can also be around 30, 45, 60, 90, 120, 135, or 150 degrees. This flexibility in rotation angles can allow for precise positioning of the wafer boat 102, enabling the optimal orientation of the wafers W for the next stage of the manufacturing process.

The rotational speed of the turntable 322 can be set to a constant value. In some embodiments, the rotational speed of turntable 322 may be variable (e.g., speed of the turntable 322 can gradually increase or decrease). In some embodiments, during three consecutive time intervals (first, second, and third time intervals), the speed of turntable 322 in the second time interval can be greater than its speed in the first and third time intervals. This variability in rotational speed can allow for fine-tuned control during the handling process, providing smoother acceleration and deceleration to prevent sudden jolts that could potentially disturb or damage the wafers W. Such speed adjustments can help in maintaining stability and minimizing vibration during stages of the wafer rotation, thereby ensuring both the safety of the wafers and the reliability of the manufacturing process. By way of example, but not limitation, the rotational speed of the turntable 322 can be in a range from about 1 to 10 seconds per rotation, such as about 1, 2, 3, 4, 5, 6, 7, 8, 9, or 10 seconds per rotation.

Reference is made to FIGS. 3 and 4C. The method M proceeds to step S4, where a first photoresist removal can be performed on the wafer W by a stripping process. The photoresist layer PR (see FIG. 4B) can be removed by, such as a dry stripping process, using a suitable gas, such as N₂, O₂, the like, or the combination thereof. After the photoresist removal, photoresist residues, which are residues of the photoresist layer PR, may remain on the wafer W. Subsequently, a second photoresist removal can be performed on the wafer W to remove the photoresist residues by, such as a wet stripping process, using a suitable gas, such as NH₂OH, H₂O, the like, or the combination thereof.

Reference is made to FIG. 3. The method M may proceed to step S5, where an alloy may be formed on the metal pad 325 exposed by the passivation layer 330. In some alternative embodiments, the step S5 (the formation of the alloy) may be skipped or omitted. The method M may then proceed to another step, where a wafer acceptance test (WAT) can be performed. By means of the WAT, the quality and the stability of the wafers are somewhat ensured.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an automatic turntable that can allow for a semiconductor boat to be rotated such that its handle is positioned for a human operator. The process can be automated to ensure that the handle of the semiconductor boat can ends up on the accessible side for personnel, thereby eliminating unsafe manual operations and promoting automation.

In some embodiments, a method includes placing a wafer boat including one or more semiconductor wafers onto an automated mechanism platform apparatus mounted on a shelf of a first rack, wherein the automated mechanism platform apparatus includes a rotor and a turntable over the rotor; utilizing a position detection system to verify a placement of the wafer boat on the turntable; rotating the wafer boat on the turntable to adjust an orientation of the wafer boat. In some embodiments, utilizing the position detection system to verify the placement of the wafer boat is performed by monitoring a light-blocking element of the wafer boat extending into a trench in the turntable. In some embodiments, rotating the wafer boat on the turntable is performed such that a handle of the wafer boat is positioned towards an accessible side for transport. In some embodiments, rotating the wafer boat on the turntable is performed by rotating the turntable by approximately 180 degrees. In some embodiments, the method further incudes generating an abnormality alert if the wafer boat is misaligned with the turntable; halting the step of rotating the wafer boat. In some embodiments, the method further incudes controlling a rotational speed of the turntable. In some embodiments, the method further incudes processing the semiconductor wafers within the wafer boat by a production tool, wherein the first rack is positioned adjacent to the production tool. In some embodiments, the method further incudes after processing the semiconductor wafers by the production tool, transferring the semiconductor wafers in the wafer boat to a second rack for a gas removal process; after the gas removal process, moving the wafer boat from the second rack to the automated mechanism platform apparatus in the first rack. In some embodiments, the first rack and the production tool are separated by a transfer module, and the wafer boat is placed on the automated mechanism platform apparatus in the first rack through the transfer module. In some embodiments, the production tool comprises an acid tank for treating the semiconductor wafers.

In some embodiments, a method includes processing, using an acid precursor generated by a production tool, semiconductor wafers within a wafer boat; after processing semiconductor wafers, transferring the wafer boat with the semiconductor wafers from the production tool to a rack; positioning the wafer boat with the semiconductor wafers onto a turntable of a turntable apparatus mounted on the rack; rotating the wafer boat using the turntable to achieve an orientation for subsequent wafer processing steps. In some embodiments, transferring the wafer boat is performed with a transfer module, the transfer module comprises a horizontal slide rail disposed between the production tool and the rack and a wafer container gripper installed on the horizontal slide rail. In some embodiments, the method further incudes verifying a placement of the wafer boat on the turntable using a position detection system. In some embodiments, a rotational speed of the turntable is about 2 to 4 seconds per rotation. In some embodiments, the method further incudes adjusting a rotational speed of the turntable.

In some embodiments, a system includes a rack, a rotor, a turntable, a position detection system, and a control system. The rack includes a plurality of shelves arranged in a vertical direction. The rotor is mounted on one of the shelves. The turntable is coupled to the rotor, wherein the turntable is configured to support a wafer boat accommodating one or more semiconductor wafers, and the rotor is configured to rotate the turntable to adjust an orientation of a wafer boat. The position detection system includes a transmitter and a receiver disposed on the one of the shelves and at opposite sides of the turntable to detect a presence of a light-blocking element of the wafer boat when the wafer boat is aligned with the turntable. The control system is communicatively connected to the rotor and the position detection system, and configured to control a rotation of the turntable and monitor an alignment of the wafer boat. In some embodiments, the turntable comprises a linear trench recessed downward from a top surface of the turntable and extending through two opposite sidewalls of the turntable, and in a rotational position of the turntable, an imaginary extension line of the linear trench aligns with the transmitter and the receiver of the position detection system, allowing the linear trench and the position detection system to function together to detect the presence of the light-blocking element of the wafer boat. In some embodiments, the turntable having a plurality of linear trenches adapted recessed downward from a top surface of the turntable to receive protruding features on a bottom of the wafer boat for securing the protruding features in position, wherein from a top view, the linear trenches extend in parallel with each other. In some embodiments, the system further includes a protective plate positioned beneath the turntable, wherein the rotor extends through an opening in the protective plate to couple with the turntable, and the protective plate further comprises a plurality of holes arranged around the rotor. In some embodiments, the system further includes a rail, positioned adjacent to the rack, and configured to transport the wafer boat along a defined path, wherein the rail extends in a direction parallel to an extension direction of the shelves within the rack, and a height of the rail is positioned below a height of the rotor and a height of the turntable.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
placing a wafer boat including one or more semiconductor wafers onto an automated mechanism platform apparatus mounted on a shelf of a first rack, wherein the automated mechanism platform apparatus includes a rotor and a turntable over the rotor;
utilizing a position detection system to verify a placement of the wafer boat on the turntable; and
rotating the wafer boat on the turntable to adjust an orientation of the wafer boat.

2. The method of claim 1, wherein utilizing the position detection system to verify the placement of the wafer boat is performed by monitoring a light-blocking element of the wafer boat extending into a trench in the turntable.

3. The method of claim 1, wherein rotating the wafer boat on the turntable is performed such that a handle of the wafer boat is positioned towards an accessible side for transport.

4. The method of claim 1, wherein rotating the wafer boat on the turntable is performed by rotating the turntable by approximately 180 degrees.

5. The method of claim 1, further comprising:
generating an abnormality alert if the wafer boat is misaligned with the turntable; and
halting the step of rotating the wafer boat.

6. The method of claim 1, further comprising:
controlling a rotational speed of the turntable.

7. The method of claim 1, further comprising:
processing the semiconductor wafers within the wafer boat by a production tool, wherein the first rack is positioned adjacent to the production tool.

8. The method of claim 7, further comprising:
after processing the semiconductor wafers by the production tool, transferring the semiconductor wafers in the wafer boat to a second rack for a gas removal process; and
after the gas removal process, moving the wafer boat from the second rack to the automated mechanism platform apparatus in the first rack.

9. The method of claim 7, wherein the first rack and the production tool are separated by a transfer module, and the wafer boat is placed on the automated mechanism platform apparatus in the first rack through the transfer module.

10. The method of claim 7, wherein the production tool comprises an acid tank for treating the semiconductor wafers.

11. A method, comprising:
processing, using an acid precursor generated by a production tool, semiconductor wafers within a wafer boat;
after processing semiconductor wafers, transferring the wafer boat with the semiconductor wafers from the production tool to a rack;
positioning the wafer boat with the semiconductor wafers onto a turntable of a turntable apparatus mounted on the rack; and
rotating the wafer boat using the turntable to achieve an orientation for subsequent wafer processing steps.

12. The method of claim 11, wherein transferring the wafer boat is performed with a transfer module, the transfer module comprises a horizontal slide rail disposed between the production tool and the rack and a wafer container gripper installed on the horizontal slide rail.

13. The method of claim 11, further comprising:
verifying a placement of the wafer boat on the turntable using a position detection system.

14. The method of claim 11, wherein a rotational speed of the turntable is about 2 to 4 seconds per rotation.

15. The method of claim 11, further comprising:
adjusting a rotational speed of the turntable.

16. A system, comprising:
a rack, comprising a plurality of shelves arranged in a vertical direction;
a rotor, mounted on one of the shelves;
a turntable, coupled to the rotor, wherein the turntable is configured to support a wafer boat accommodating one or more semiconductor wafers, and the rotor is configured to rotate the turntable to adjust an orientation of a wafer boat;
a position detection system, comprising a transmitter and a receiver disposed on the one of the shelves and at opposite sides of the turntable to detect a presence of a light-blocking element of the wafer boat when the wafer boat is aligned with the turntable; and
a control system, communicatively connected to the rotor and the position detection system, and configured to control a rotation of the turntable and monitor an alignment of the wafer boat.

17. The system of claim 16, wherein the turntable comprises a linear trench recessed downward from a top surface of the turntable and extending through two opposite sidewalls of the turntable, and in a rotational position of the turntable, an imaginary extension line of the linear trench aligns with the transmitter and the receiver of the position detection system, allowing the linear trench and the position detection system to function together to detect the presence of the light-blocking element of the wafer boat.

18. The system of claim 16, wherein the turntable having a plurality of linear trenches adapted recessed downward from a top surface of the turntable to receive protruding features on a bottom of the wafer boat for securing the protruding features in position, wherein from a top view, the linear trenches extend in parallel with each other.

19. The system of claim 16, further comprising:
a protective plate positioned beneath the turntable, wherein the rotor extends through an opening in the protective plate to couple with the turntable, and the protective plate further comprises a plurality of holes arranged around the rotor.

20. The system of claim 16, further comprising:
a rail, positioned adjacent to the rack, and configured to transport the wafer boat along a defined path, wherein the rail extends in a direction parallel to an extension direction of the shelves within the rack, and a height of the rail is positioned below a height of the rotor and a height of the turntable.
